(19) United States
(12) Patent Application Publication
(10) Pub. No.: US 2013/0127697 A1
(43) Pub. Date: May 23, 2013

(54) DISPLAY PANEL AND MULTIPLEXER CIRCUIT THEREIN, AND METHOD FOR TRANSMITTING SIGNALS IN DISPLAY PANEL

(71) Applicants: Nan-Ying LIN, Hsin-Chu (TW); Yu-Hsin TING, Hsin-Chu (TW); Chung-Lung LI, Hsin-Chu (TW); Chung-Lin FU, Hsin-Chu (TW); Wei-Chun HSU, Hsin-Chu (TW); Pei-Hua CHEN, Hsin-Chu (TW)

(72) Inventors: Nan-Ying LIN, Hsin-Chu (TW); Yu-Hsin TING, Hsin-Chu (TW); Chung-Lung LI, Hsin-Chu (TW); Chung-Lin FU, Hsin-Chu (TW); Wei-Chun HSU, Hsin-Chu (TW); Pei-Hua CHEN, Hsin-Chu (TW)

(73) Assignee: AU Optronics Corporation, Hsin-Chu (TW)

(21) Appl. No.: 13/458,026

(22) Filed: Apr. 27, 2012

(30) Foreign Application Priority Data
Nov. 18, 2011 (TW) 100142378

(51) Int. Cl. G09G 3/36; H03K 17/56

(52) U.S. Cl. 345/90; 327/419

(57) ABSTRACT

A multiplexer circuit includes multiple groups of switches and multiple groups of control lines. Each control line in each one of the groups of control lines is coupled to a control end of at least one switch in corresponding one of the groups of switches, and each group of control lines is configured for synchronously transmitting an identical group of control signals. A display panel and method for transmitting signals in a display panel is also disclosed herein.

### RELATED APPLICATIONS

This application claims priority to Taiwan Patent Application Serial Number 100142378, filed Nov. 18, 2011, which is herein incorporated by reference.

### BACKGROUND

1. Technical Field

The present disclosure relates to a display device. More particularly, the present disclosure relates to a multiplexer circuit in a display device.

2. Description of Related Art

In recent years, a liquid crystal display (LCD) is commonly used as a display device because of its capability of displaying images with good quality while using lower power. However, since the quality of the displayed image is required to be better and better, the display device must display the image with a higher resolution, and therefore, the circuit design for the display device becomes more complex, resulting in that the resistive and capacitive (RC) loadings and the effects thereof on signal transmission lines in the display device become more significant, thereby further causing distortions of transmission signals and affecting the quality of the image displayed by the display device.

Moreover, a transistor made of InGaZn Oxide (IGZO) has advantages such as high electron mobility, so it has higher current driving capability and thus IGZO can be used as the material for fabricating the display device. However, when it is applied in the display device displaying the image with a higher resolution, the RC loadings and the effects thereof on the control lines are more significant as well.

For example, FIG. 1 is a diagram illustrating a display panel, and the display panel 100 includes a display array 110, a processing circuit 120 and a number of control lines (e.g., CTRL1, CTL2, . . . , CTRLK), in which the display array 110 has N data lines (e.g., DL1, DL2, . . . , DLN) and M scan lines (e.g., GL1, GL2, . . . , GLM). The data lines interlace with the scan lines, and the processing circuit 120 is connected to the data lines DL1, DL2, . . . , DLN. In addition, each of the control lines CTRL1, CTL2, . . . , CTRLK is connected through the processing circuit 120 to several data lines of the data lines DL1, DL2, . . . , DLN.

In operation, the control signals are transmitted to the processing circuit 120 through the control lines CTRL1, CTL2, . . . , CTRLK, such that the processing circuit 120 operates according to the control signals, and furthermore video signals SL1, SL2, . . . , SLP can be transmitted to the data lines DL1, DL2, . . . , DLN through the processing circuit 120, so as to drive the data lines DL1, DL2, . . . , DLN.

However, since each of the control lines CTRL1, CTL2, . . . , CTRLK is connected to several data lines of the data lines DL1, DL2, . . . , DLN through the processing circuit 120 (e.g., the control line CTRL1 is connected to the data lines DL1, DL3, DL5, etc., through the processing circuit 120), the resistive and capacitive (RC) loading and its effect on each control line are significant, such that the control signals on the control lines have distortions, and the related circuits or data lines may not operate normally, thereby further affect the quality of the image.

### SUMMARY

An aspect of the present invention is to provide a multiplexer circuit comprising a plurality of switches, a first group of control lines and a second group of control lines. The switches comprise a first group of switches and a second group of switches. Each of the first group of control lines is coupled to a control end of at least one of the first group of switches, and the first group of control lines is configured to transmit a first group of control signals. Each of the second group of control lines is coupled to a control end of at least one of the second group of switches, and the second group of control lines is configured to synchronously transmit a second group of control signals which are the same as the first group of control signals.

Another aspect of the present invention is to provide a display panel comprising a plurality of scan lines, a plurality of data lines, and a multiplexer circuit. The data lines interlace with the scan lines. The multiplexer circuit comprises a plurality of switches and a plurality of groups of control lines. First ends of the switches are coupled to one ends of the data lines. Two of the groups of control lines are coupled to control ends of different ones of the switches, respectively, and the groups of control lines are configured to synchronously transmit a plurality of identical groups of control signals.

Still another aspect of the present invention is to provide a method for transmitting signals, applicable for the display panel as described in the immediately previous paragraph. The method comprises synchronously transmitting a plurality of identical groups of control signals through the groups of control lines to a plurality of groups of corresponding switches, the groups of switches being activated in accordance with the groups of control signals, and transmitting a plurality of video signals through a plurality of corresponding video signal lines and the activated switches to the data lines.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference to the accompanying drawings as follows:

FIG. 1 is a diagram illustrating a display panel;

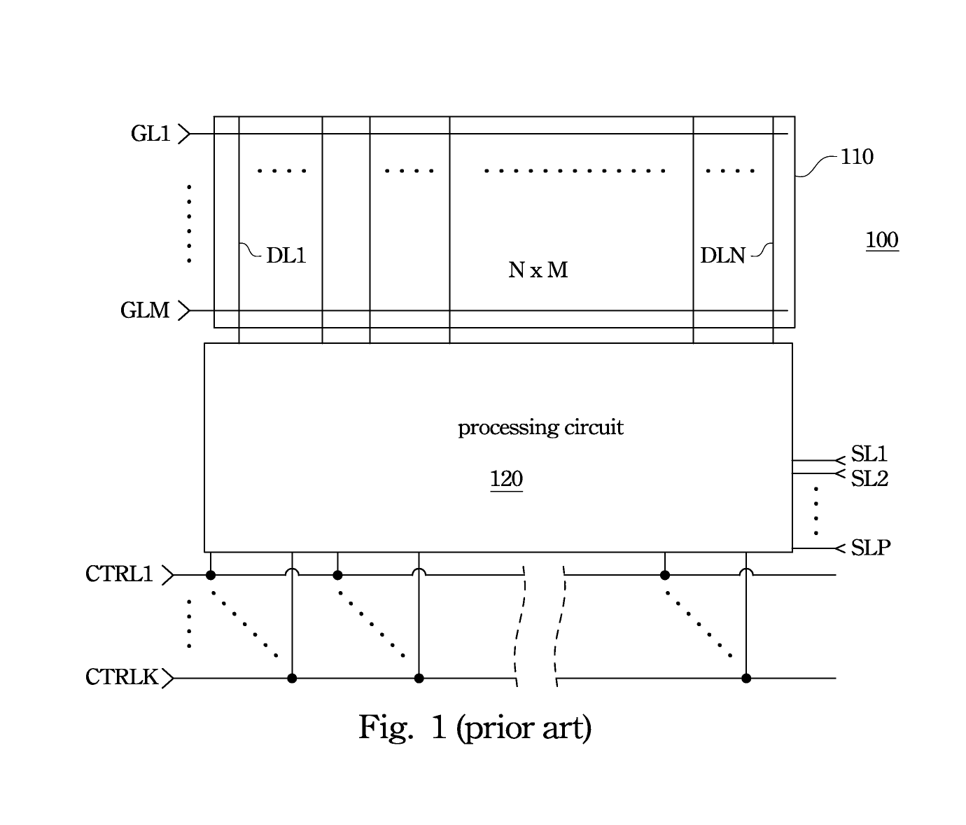

FIG. 2 is a diagram illustrating a display panel according to a first embodiment of the present invention;

FIG. 3 is a timing diagram of the control signals transmitted in a scan signal period by the control lines of the multiplexer circuit shown in FIG. 2;

FIG. 4 is a diagram illustrating waveforms of the signals on two adjacent control lines shown in FIG. 3 under an ideal condition and a condition that the RC loading is considered, respectively;

FIG. 5 is a diagram illustrating a display panel according to a second embodiment of the present invention;

FIG. 6 is a diagram illustrating a display panel according to a third embodiment of the present invention;

FIG. 7 is a diagram illustrating a display panel according to a fourth embodiment of the present invention;

FIG. 8 is a diagram illustrating a display panel according to a fifth embodiment of the present invention;

FIG. 9 is a diagram illustrating a display panel according to a sixth embodiment of the present invention; and

FIG. 10 is a diagram illustrating a display panel according to a seventh embodiment of the present invention.

### DESCRIPTION OF THE EMBODIMENTS

In the following description, specific details are presented to provide a thorough understanding of the embodiments of the present invention. Persons of ordinary skill in the relevant art will recognize, however, that the present invention can be practiced without one or more of the specific details, or in combination with other components. Well-known implementations or operations are not shown or described in detail to avoid obscuring aspects of various embodiments of the present invention.

The terms used in this specification generally have their ordinary meanings in the art and in the specific context where each term is used. The use of examples anywhere in this specification, including examples of any terms discussed herein, is illustrative only, and in no way limits the scope and meaning of the invention or of any exemplified term. Likewise, the present invention is not limited to various embodiments given in this specification.

As used herein, the terms “comprising,” “including,” “having,” “containing,” “involving,” and the like are to be understood to be open-ended, i.e., to mean including but not limited to.

Reference throughout the specification to “one embodiment” or “an embodiment” means that a particular feature, structure, implementation, or characteristic described in connection with the embodiment is included in at least one embodiment of the present invention. Thus, uses of the phrases “in one embodiment” or “in an embodiment” in various places throughout the specification are not necessarily all referring to the same embodiment. Furthermore, the particular features, structures, implementation, or characteristics may be combined in any suitable manner in one or more embodiments.

In the following description and claims, the terms “coupled” and “connected”, along with their derivatives, may be used. In particular embodiments, “connected” and “coupled” may be used to indicate that two or more elements are in direct physical or electrical contact with each other, or may also mean that two or more elements may not be in direct contact with each other. “Coupled” may still be used to indicate that two or more elements cooperate or interact with each other.

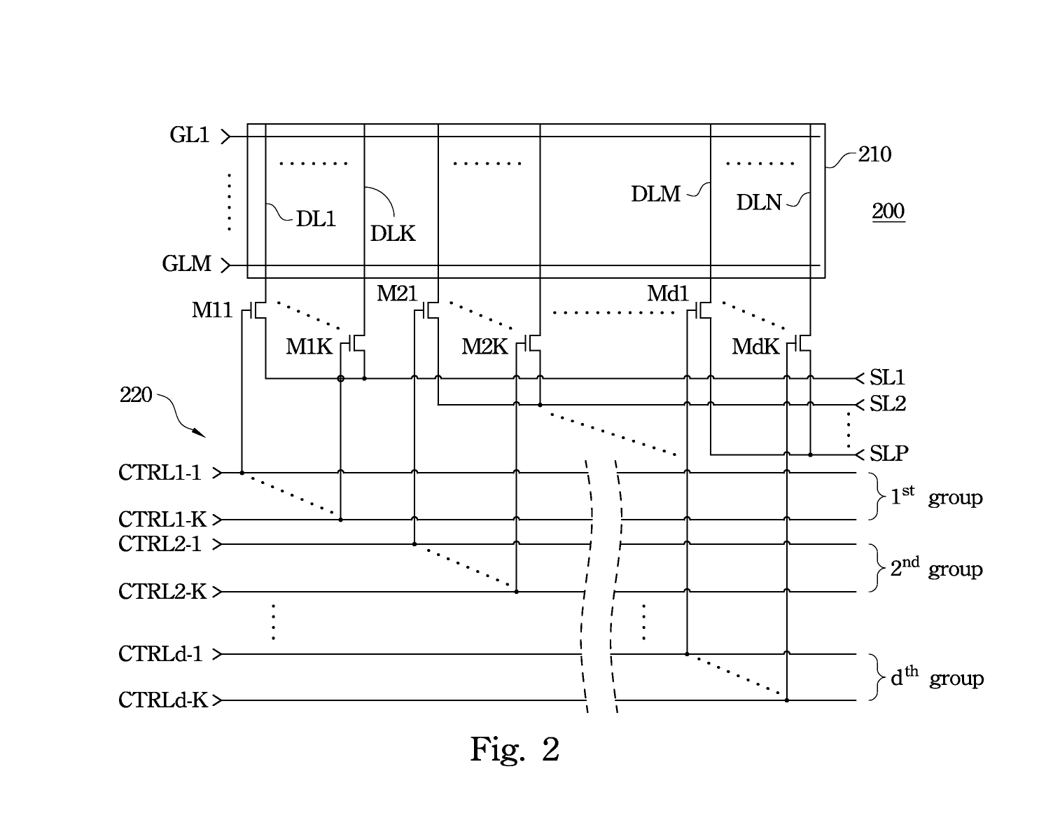

FIG. 2 is a diagram illustrating a display panel according to a first embodiment of the present invention. The display panel 200 includes a display array 210 and a multiplexer circuit 220, in which the multiplexer circuit 220 is electrically coupled to the display array 210.

The display array 210 includes a plurality of data lines (e.g., N data lines DL1-DLN, where N is a positive integer) and a plurality of scan lines (e.g., M scan lines GL1-GLM, where M is a positive integer), and the data lines interlace with the scan lines to form a pixel array. In the present embodiment, the data lines DL1-DLN are coupled to the multiplexer circuit 220 and configured to receive video signals according to the operation of the multiplexer circuit 220.

On the other hand, the multiplexer circuit 220 includes a plurality of switches and a plurality of control lines, in which the switches may further be separated into several groups of switches, the control lines may further be separated into several groups of control lines, each control line in each group of control lines is coupled to a control end of at least one switch in the corresponding one group of switches, and two of the groups of control lines are configured to synchronously transmit two identical groups of control signals.

Specifically, as illustrated in FIG. 2, the multiplexer circuit 220 includes a 1^{st} group of switches M11-M1K, a 2^{nd} group of switches M21-M2K, . . . , and a d^{th} group of switches Md1-MdK, and includes a 1^{st} group of control lines CTRL1-1-CTRL1-K, a 2^{nd} group of control lines CTRL2-1-CTRL2-K, . . . , and a d^{th} group of control lines CTRLd-1-CTRLd-K, in which the control lines are different from one another and coupled to the different corresponding switches, respectively, where d and K are positive integers. The 1^{st} group of control lines CTRL1-1-CTRL1-K is coupled to the control ends of the corresponding 1^{st} group of switches M1′-M1K, the 2^{nd} group of control lines CTRL2-1-CTRL2-K is coupled to the control ends of the corresponding 2^{nd} group of switches M21-M2K, the d^{th} group of control lines CTRLd-1-CTRLd-K is coupled to the control ends of the corresponding d^{th} group of switches Md1-MdK, and so on.

In practice, each of the aforementioned switches may be an analog switch, a digital switch, a thin-film transistor switch or the other type of switch, the appropriate type of switch can be selected and used by persons of ordinary skill in the art according to practical needs for the design of the multiplexer circuit 220, and thus the types of the aforementioned switches are not limited. In one embodiment, each of the aforementioned switches may further include a transistor made of InGaZn Oxide (IGZO).

In addition, in one embodiment, any two group of control lines are coupled to the control ends of the different switches, respectively; in other words, the switches coupled to one group of control lines are different from the switches coupled to the other group of control lines. For example, the 1^{st} group of control lines CTRL1-1-CTRL1-K is coupled to the switches M11-M1K, the switches M31-M3K, etc., the 2^{nd} group of control lines CTRL2-1-CTRL2-K is coupled to the switches M21-M2K, the switches M41-M4K, etc., and the switches coupled to the 1^{st} group of control lines are different from the switches coupled to the 2^{nd} group of control lines.

It is noted that, in practice, each of the aforementioned control lines may be coupled to the control ends of two or more than two switches according to practical needs. Therefore, the connections of the control lines and the switches shown in FIG. 2 are merely illustrative and convenient for description but not limiting of the present invention.

Moreover, as illustrated in FIG. 2, the display panel 200 may further include a plurality of video signal lines (e.g., P video signal lines SL1-SLP, where P is a positive integer), in which each of the video signal lines SL1-SLP is coupled to second ends of the switches corresponding to one group of control lines, and first ends of the switches corresponding to the same group of control lines are coupled to one ends of the data lines DL1-DLN, respectively.

For example, the first ends of the 1^{st} group of switches M11-M1K are coupled to the data lines DL1-DLK, respectively, and the video signal line SL1 is coupled to the second ends of the 1^{st} group of switches M11-M1K. Furthermore, the first ends of the d^{th} group of switches Md1-MdK are coupled to the data lines DLM-DLN, respectively, and the video signal line SLP is coupled to the second ends of the d^{th} group of switches Md1-MdK.

Therefore, when the switches M11-M1K are sequentially activated (or turned on) according to the control signals transmitted by the control lines CTRL1-1-CTRL1-K, the video signal transmitted by the video signal line SL1 can be transmitted to the data lines DL1-DLK sequentially through the switches M11-M1K correspondingly. In addition, when the switches Md1-MdK are sequentially activated (or turned on) according to the control signals transmitted by the control lines CTRLd-1-CTRLd-K, the video signal transmitted by the video signal line SLP can be transmitted to the data lines DLM-DLN sequentially through the switches Md1-MdK correspondingly.

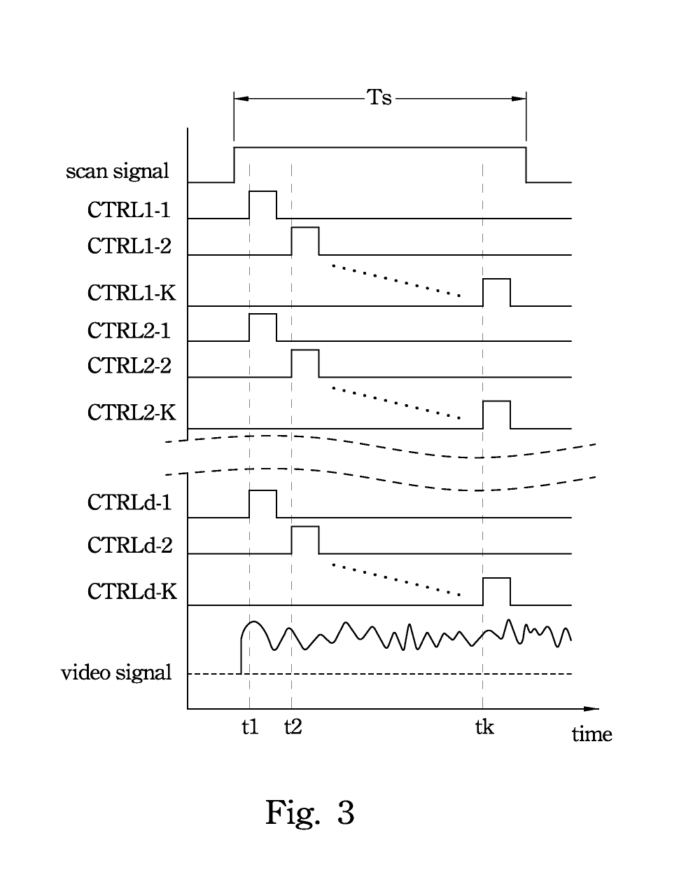

FIG. 3 is a timing diagram of the control signals transmitted in a scan signal period by the control lines of the multiplexer circuit shown in FIG. 2. As illustrated in FIG. 2 and FIG. 3, the 1^{st} group, the 2^{nd} group, . . . , and the d^{th} group of control lines are configured to synchronously transmit a plurality of identical groups of control signals; in other words, each of the 1^{st} group, the 2^{nd} group, . . . , and the d^{th} group of control lines synchronously transmits a group of control signals. In one embodiment, each of the 1^{st} group, the 2^{nd} group, . . . , and the d^{th} group of control lines is configured to synchronously transmit a group of control signals in a scan signal period Ts during which a scan signal is transmitted by one of the scan lines, e.g., GL1.

Specifically, the 1^{st} group of control lines CTRL1-1-CTRL1-K sequentially transmit the control signals, the 2^{nd} group of control lines CTRL2-1-CTRL2-K is synchronized with the 1^{st} group of control lines and sequentially transmit the control signals, the d^{th} group of control lines CTRLd-1-CTRLd-K is synchronized with the 1^{st} group of control lines and sequentially transmit the control signals, and so on. In other words, the control lines CTRL1-1, CTRL2-1, CTRLd-1 synchronously transmit the control signals, the control lines CTRL1-2, CTRL2-2, CTRLd-2 synchronously transmit the control signals, and the control lines CTRL1-K, CTRL2-K, CTRLd-K synchronously transmit the control signals, and so on.

In one embodiment, the control signals transmitted by each group of control lines includes a plurality of clock signals, and phases of the clock signals are different from one another; that is, any two of the clock signals have a phase difference therebetween. For example, the 1^{st} group of control lines CTRL1-1-CTRL1-K sequentially transmit the clock signals in the time period t1, t2, . . . , tk, respectively, such that the phases of the clock signals transmitted by the control lines CTRL1-1-CTRL1-K are different from one another, and any two of the clock signals transmitted by the control lines CTRL1-1-CTRL1-K have a phase difference therebetween, such that the switches corresponding to the control lines CTRL1-1-CTRL1-K are sequentially activated to transmit the signals.

The operation of the display panel 200 shown in FIG. 2 is exemplified and described below in conjunction with one embodiment. Referring to FIG. 2 and FIG. 3, in a scan signal period during which a scan signal is transmitted by a scan line (e.g., GL1), the 1^{st} control lines CTRL1-1, CTRL2-1, . . . , CTRLd-1 separately in the 1^{st} group, the 2^{nd} group, . . . , and the d^{th} group of control lines synchronously transmit the identical groups of control signals in the time period t1 to the corresponding switches M11, M21, . . . , Md1, respectively, such that the 1^{st} switches M11, M21, . . . , Md1 separately in the groups of switches are activated according to the control signals, and the video signals transmitted by the video signal lines SL1-SLP are transmitted through the corresponding switches M11, M21, . . . , Md1, respectively, to the data lines DL1, . . . , DLM.

Thereafter, the K^{th} control lines CTRL1-K, CTRL2-K, . . . , CTRLd-K separately in the 1^{st} group, the 2^{nd} group, . . . , and the d^{th} group of control lines synchronously transmit the identical groups of control signals in another time period tk to the corresponding switches M1K, M2K, . . . , MdK, respectively, such that the K^{th} switches M1K, M2K, . . . , MdK separately in the groups of switches are activated according to the control signals, and the video signals transmitted by the video signal lines SL1-SLP are transmitted through the corresponding switches M1K, M2K, . . . , MdK, respectively, to the data lines DLK, . . . , DLN.

In the condition that the number of the data lines is N, if only K control lines CTRL1-1, . . . , CTRL1-K are coupled to the data lines through the switches, each of the control lines is ideally coupled to N/K switches (where N and K are positive integers, and N is greater than K); in other words, the resistive and capacitive (RC) loading on each control line is basically represented by N×C×R/K, in which C and R are a capacitive loading and a resistive loading, respectively, on a single control line.

Compared to the condition described above, in the embodiment of the present invention, the multiplexer circuit 220 includes d groups of control lines (where d is a positive integer), and each group of control lines includes K control lines, then each of the control lines is ideally coupled to N/(K×d) switches; in other words, the resistive and capacitive (RC) loading on each control line is basically represented by N×C×R/(K×d). Therefore, the RC loading on each control line and its effect can be reduced significantly, the distortions of the control signals on the control lines also can be decreased, and the quality of the display image can be improved accordingly.

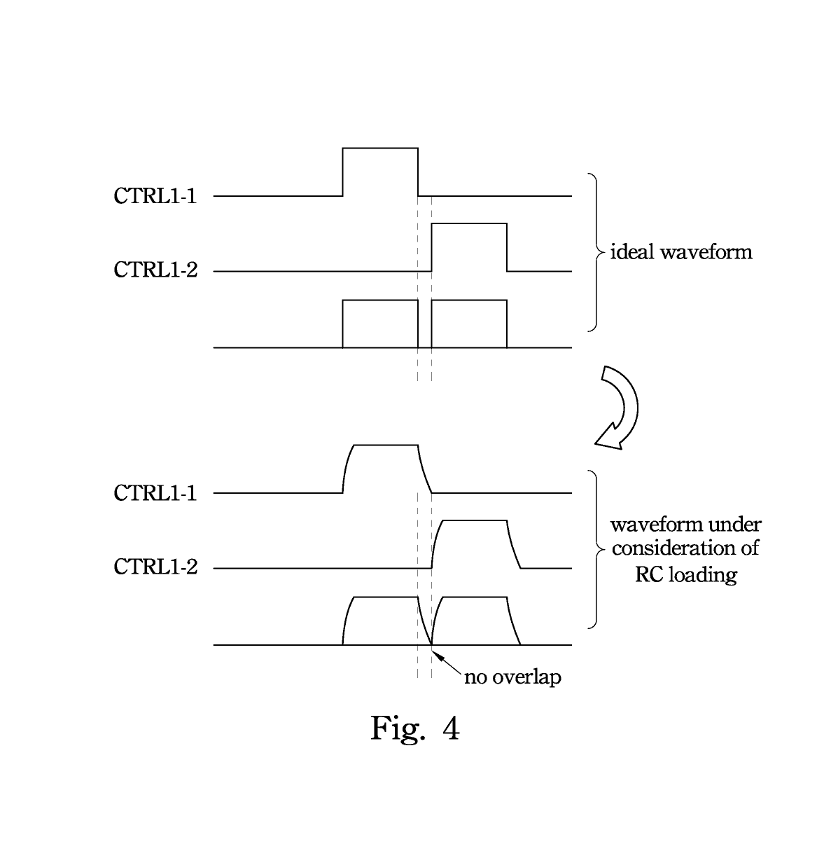

FIG. 4 is a diagram illustrating waveforms of the signals on two adjacent control lines shown in FIG. 3 under an ideal condition and a condition that the RC loading is considered, respectively. As illustrated in FIG. 4, compared to the ideal condition, under the condition that the RC loading is considered, the control signals on the adjacent control lines CTRL1-1 and CTRL1-2 may have distortions. However, in the embodiment of the present invention, the RC loading on each control line is reduced significantly such that the distortions of the control signals on the control lines are also decreased and thus the transmission delays of the signals are improved, so the control signals on the adjacent control lines CTRL1-1 and CTRL1-2 have no overlap.

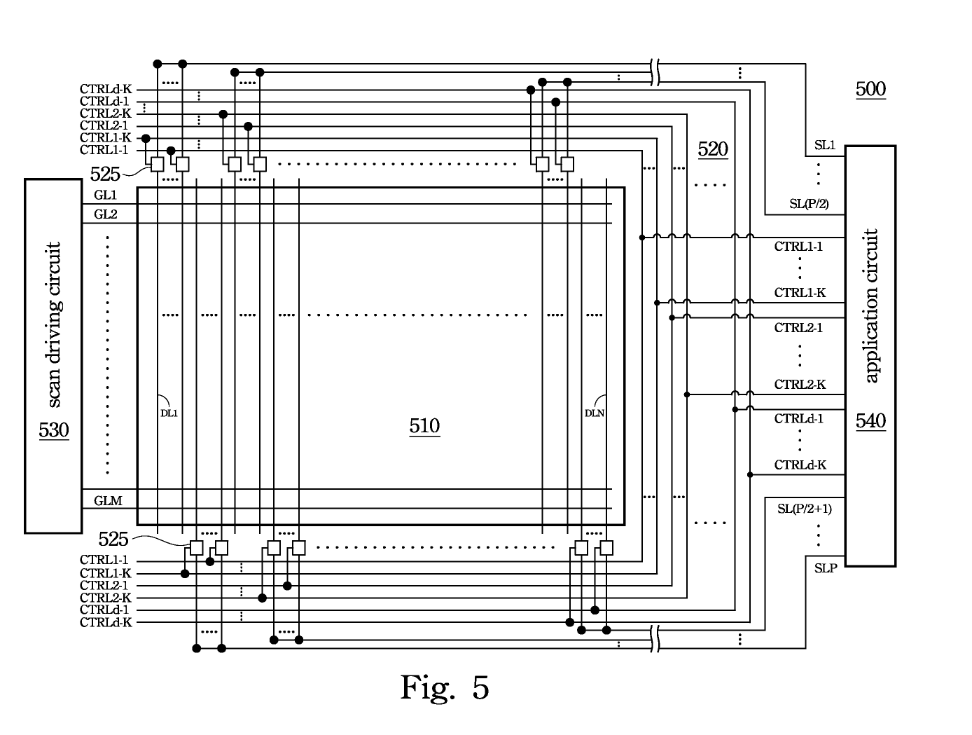

FIG. 5 is a diagram illustrating a display panel according to a second embodiment of the present invention. As illustrated in FIG. 5, the display panel 500 includes a display array 510, a multiplexer circuit 520, a scan driving circuit 530, an application circuit 540 and video signal lines SL1-SLP, in which the scan driving circuit 530 and the application circuit 540 may be arranged at opposite sides of the display array 510. The display array 510 includes the data lines DL1-DLN and the scan lines GL1-GLM, and the data lines DL1-DLN interlace with the scan lines GL1-GLM to form a pixel array. Furthermore, the scan driving circuit 530 is coupled to the scan lines GL1-GLM and configured to output the scan signals sequentially transmitted through the scan lines GL1-GLM.

The multiplexer circuit 520 in the present embodiment is similar to the multiplexer circuit 220 shown in FIG. 2. The multiplexer circuit 520 includes multiple groups of switches (each group includes multiple switches 525) and d groups of control lines (e.g., CTRL1-1-CTRL1-K, . . . , CTRLd-1-CTRLd-K), in which each control line is coupled to the control end of at least one switch 525, and any two groups of control lines are configured to synchronously transmit identical control signals. In addition, similar to the configuration shown in FIG. 2, the multiple switches 525 are correspondingly coupled to the data lines DL1-DLN and the video signal lines SL1-SLP, such that the video signals on the video signal lines SL1-SLP can be transmitted to the data lines DL1-DLN when the switches 525 are activated according to the control signals on the control lines.

Likewise, each of the switches 525 may be an analog switch, a digital switch, a thin-film transistor switch or the other type of switch, and the appropriate type of switch can be selected and used by persons of ordinary skill in the art according to practical needs for the design of the multiplexer circuit 520.

Moreover in practice, each of the control lines may be coupled to the control end of at least one switch 525 or coupled to the control ends of two or more than two switches 525 according to practical needs. Therefore, the connections of the control lines and the switches shown in FIG. 5 are merely illustrative and convenient for description but not limiting of the present invention.

On the other hand, the application circuit 540 is coupled to the video signal lines SL1-SLP and the d groups of control lines. The application circuit 540 is configured for generating the video signals transmitted through the video signal lines SL1-SLP and configured for generating the multiple groups of control signals transmitted synchronously through the multiple groups of control lines. In practice, the application circuit 540 in the present embodiment or the application circuit described in the following embodiments can be an application specific integrated circuit (ASIC) or other circuits with the same function and operation.

The operation of the display panel 500 in the present embodiment is similar to that of the display panel 200 shown in FIG. 2. For example, referring to FIG. 3 and FIG. 5, when the scan driving circuit 530 outputs the scan signal for driving the scan line GL1, in the period of the scan signal on the scan line GL1 the 1^{st} group of control lines CTRL1-1-CTRL1-K through the d^{th} group of control lines CTRLd-1-CTRLd-K synchronously transmit the identical control signals to the corresponding switches 525, respectively, such that the corresponding switches 525 are activated according to the control signals, and the video signals on the video signal lines SL1-SLP are transmitted to the corresponding data lines through the corresponding switches 525, respectively.

Similarly, the multiplexer circuit 520 includes d groups of control lines, and each group of control lines includes K control lines, so the resistive and capacitive (RC) loading on each control line is basically represented by N×C×R/(K×d). Therefore, the RC loading on each control line and its effect can be reduced significantly, the distortions of the control signals on the control lines also can be decreased, and the quality of the display image can be improved accordingly.

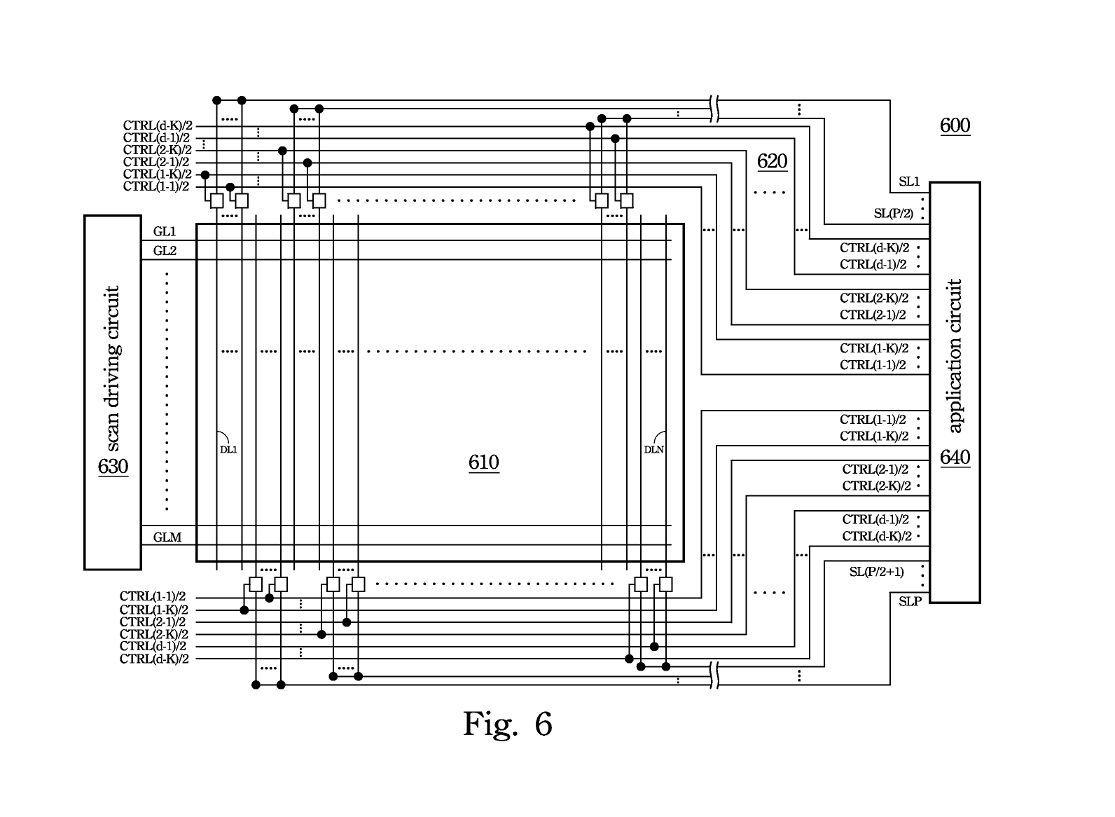

FIG. 6 is a diagram illustrating a display panel according to a third embodiment of the present invention. As illustrated in FIG. 6, the display panel 600 includes a display array 610, a multiplexer circuit 620, a scan driving circuit 630, an application circuit 640 and video signal lines SL1-SLP. The connections and operations of the display array 610, the multiplexer circuit 620, the scan driving circuit 630, the application circuit 640 and the video signal lines SL1-SLP are similar to those in the aforementioned embodiments, and thus they are not further detailed hereinafter.

The multiplexer circuit 620 in the present embodiment includes more groups of control lines, e.g., 2d groups. Specifically, the upper part of FIG. 6 includes d groups of control lines CTRL(1-1)/2-CTRL(1-K)/2, . . . , and CTRL(d-1)/2−CTRL(d-K)/2, and the lower part of FIG. 6 also includes d groups of control lines CTRL(1-1)/2-CTRL(1-K)/2, . . . , and CTRL(d-1)/2-CTRL(d-K)/2; in other words, compared to the multiplexer circuit 520 shown in FIG. 5, the number of the control lines in the multiplexer circuit 620 is twice the number of the control lines in the multiplexer circuit 520.

In the present embodiment, the multiplexer circuit 620 includes 2d groups of control lines, and each group of control lines includes K control lines, so the resistive and capacitive (RC) loading on each control line is basically represented by N×C×R/(2×K×d). Therefore, compared to the embodiment shown in FIG. 5, the RC loading on each control line and its effect in the present embodiment can further be reduced significantly, and the distortions of the control signals on the control lines also can further be decreased.

In practice, each of the aforementioned control lines may be coupled to the control end of one or more than one switch or coupled to the control ends of two or more than two switches according to practical needs. Therefore, the connections of the control lines and the switches shown in FIG. 6 are merely illustrative and convenient for description but not limiting of the present invention. In addition, the number of the control lines described in the present embodiment is merely illustrative but not limiting of the present invention; that is, the number of the control lines also can be increased to be more than twice the number of the control lines shown in FIG. 5.

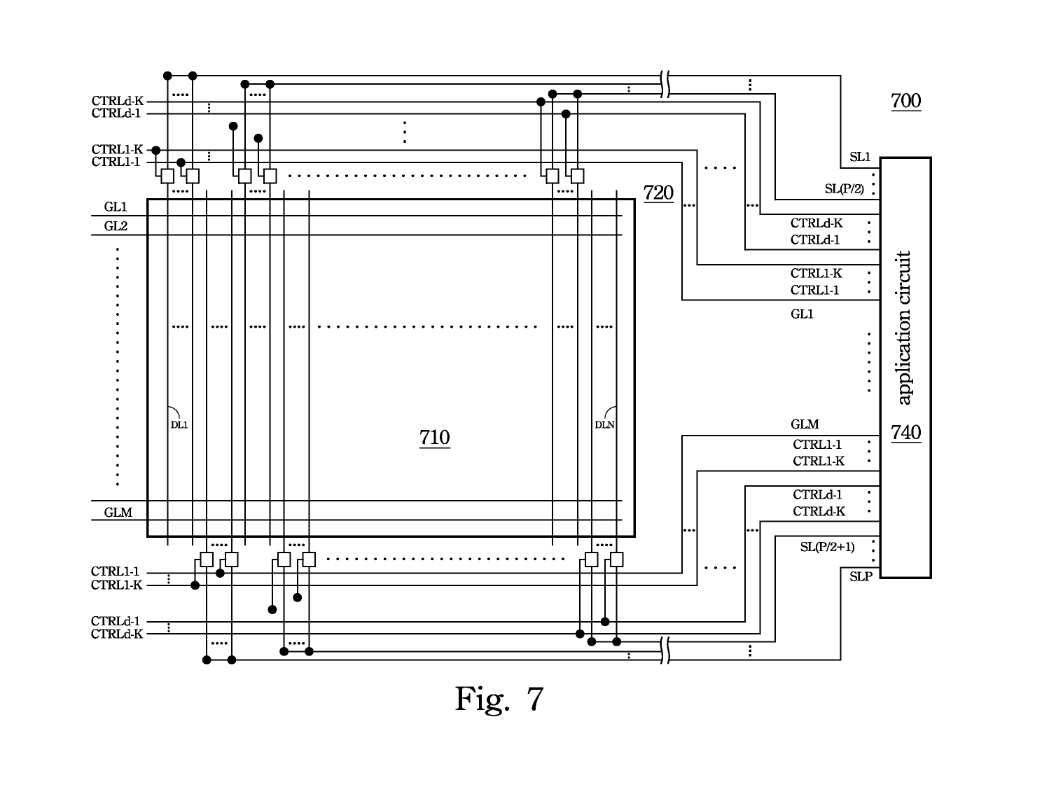

FIG. 7 is a diagram illustrating a display panel according to a fourth embodiment of the present invention. As illustrated in FIG. 7, the display panel 700 includes a display array 710, a multiplexer circuit 720, an application circuit 740 and video signal lines SL1-SLP, in which the display array 710 includes the data lines DL1-DLN and the scan lines GL1-GLM, and the application circuit 740 is, for example, arranged at one side (e.g., a right side) of the display array 710. The connections and operations of the display array 710, the multiplexer circuit 720, the application circuit 740 and the video signal lines SL1-SLP are similar to those in the aforementioned embodiments, and thus they are not further detailed hereinafter.

In the present embodiment, the application circuit 740 is coupled to the video signal lines SL1-SLP, the d groups of control lines (e.g., CTRL1-1-CTRL1-K, . . . , CTRLd-1-CTRLd-K) and the scan lines GL1-GLM, in which the application circuit 740 is configured for generating the video signals transmitted through the video signal lines SL1-SLP, configured for generating the multiple groups of control signals transmitted synchronously through the multiple groups of control lines, and further configured for generating the scan signals transmitted through the scan lines GL1-GLM. In other words, compared to the display panel 500 shown in FIG. 5, the display panel 700 in the present embodiment includes no scan driving circuit, and the application circuit 740 generates the scan signals transmitted through the scan lines GL1-GLM.

In practice, each of the aforementioned control lines may be coupled to the control end of one or more than one switch or coupled to the control ends of two or more than two switches according to practical needs. Therefore, the connections shown in FIG. 7 are merely illustrative and convenient for description but not limiting of the present invention.

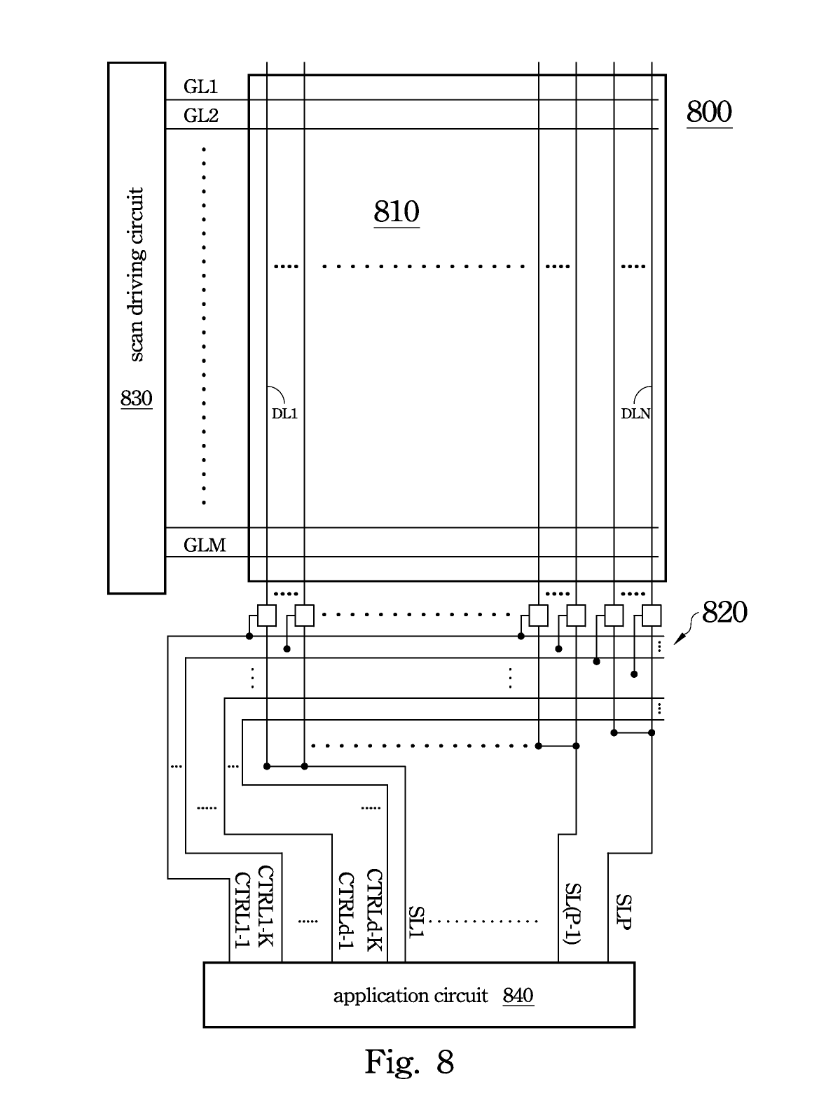

FIG. 8 is a diagram illustrating a display panel according to a fifth embodiment of the present invention. As illustrated in FIG. 8, the display panel 800 includes a display array 810, a multiplexer circuit 820, a scan driving circuit 830, an application circuit 840 and video signal lines SL1-SLP. The connections and operations of the display array 810, the multiplexer circuit 820, the scan driving circuit 830, the application circuit 840 and the video signal lines SL1-SLP are similar to those in the embodiment shown in FIG. 5, and thus they are not further detailed hereinafter.

Compared to the embodiment in FIG. 5, the arrangements of the multiplexer circuit 820 and the application circuit 840 in the present embodiment are different from those of the multiplexer circuit and the application circuit shown in FIG. 5. Specifically, the multiplexer circuit 820 and the application circuit 840 are arranged at the lower part of FIG. 8, e.g., the part below the display array 810. For example, the scan driving circuit 830 is arranged at a first side (e.g., a left side) of the display array 810, and the multiplexer circuit 820 and the application circuit 840 are arranged at a second side (e.g., a lower side) adjacent to the first side (e.g., the left side) of the display array 810. Thus, compared to the embodiment in FIG. 5, the present embodiment is applicable to other types of electronic products (e.g., portable devices such as flat panel computer, smart phone, etc.)

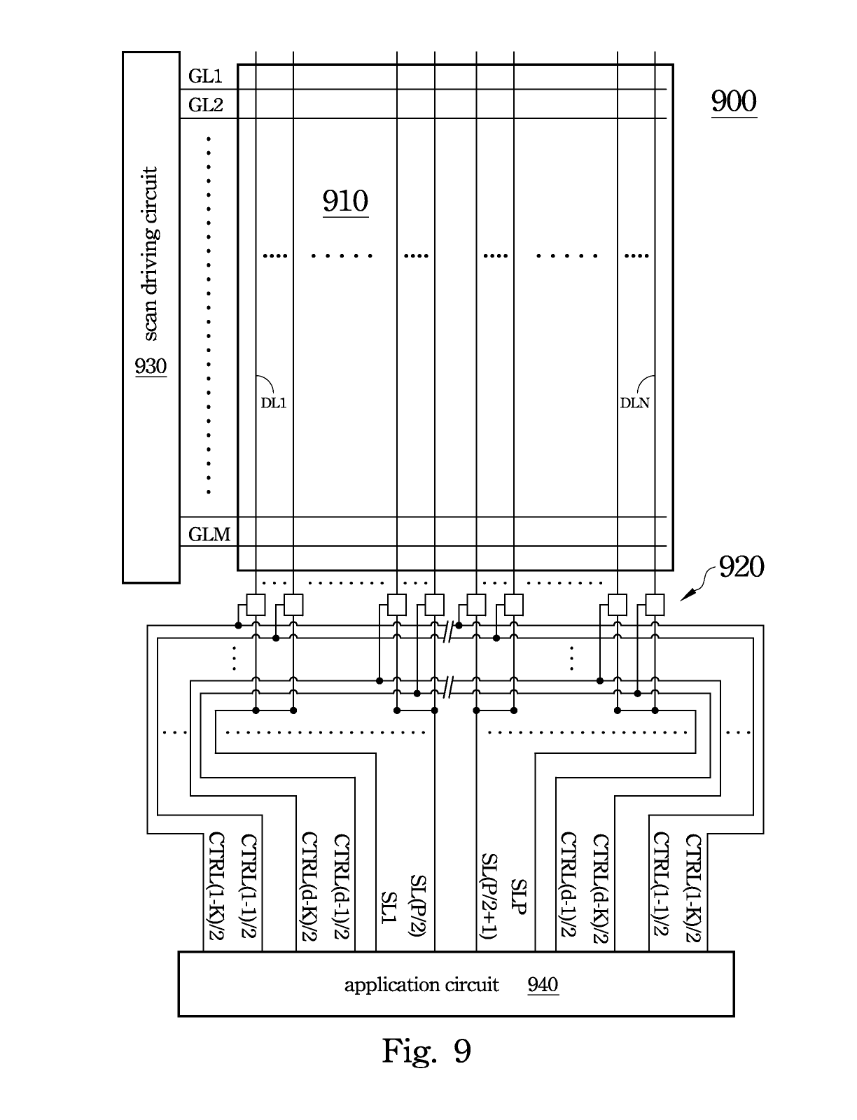

FIG. 9 is a diagram illustrating a display panel according to a sixth embodiment of the present invention. As illustrated in FIG. 9, the display panel 900 includes a display array 910, a multiplexer circuit 920, a scan driving circuit 930, an application circuit 940 and video signal lines SL1-SLP. The connections and operations of the display array 910, the multiplexer circuit 920, the scan driving circuit 930, the application circuit 940 and the video signal lines SL1-SLP are similar to those in the embodiment shown in FIG. 6, and thus they are not further detailed hereinafter.

Compared to the embodiment in FIG. 6, the arrangements of the multiplexer circuit 920 and the application circuit 940 in the present embodiment are different from those of the multiplexer circuit and the application circuit shown in FIG. 6; instead, the multiplexer circuit 920 and the application circuit 940 are arranged at the lower part of FIG. 9, which are similar to those shown in FIG. 8. For example, the scan driving circuit 930 is arranged at a first side (e.g., a left side) of the display array 910, and the multiplexer circuit 920 and the application circuit 940 are arranged at a second side (e.g., a lower side) adjacent to the first side (e.g., the left side) of the display array 910.

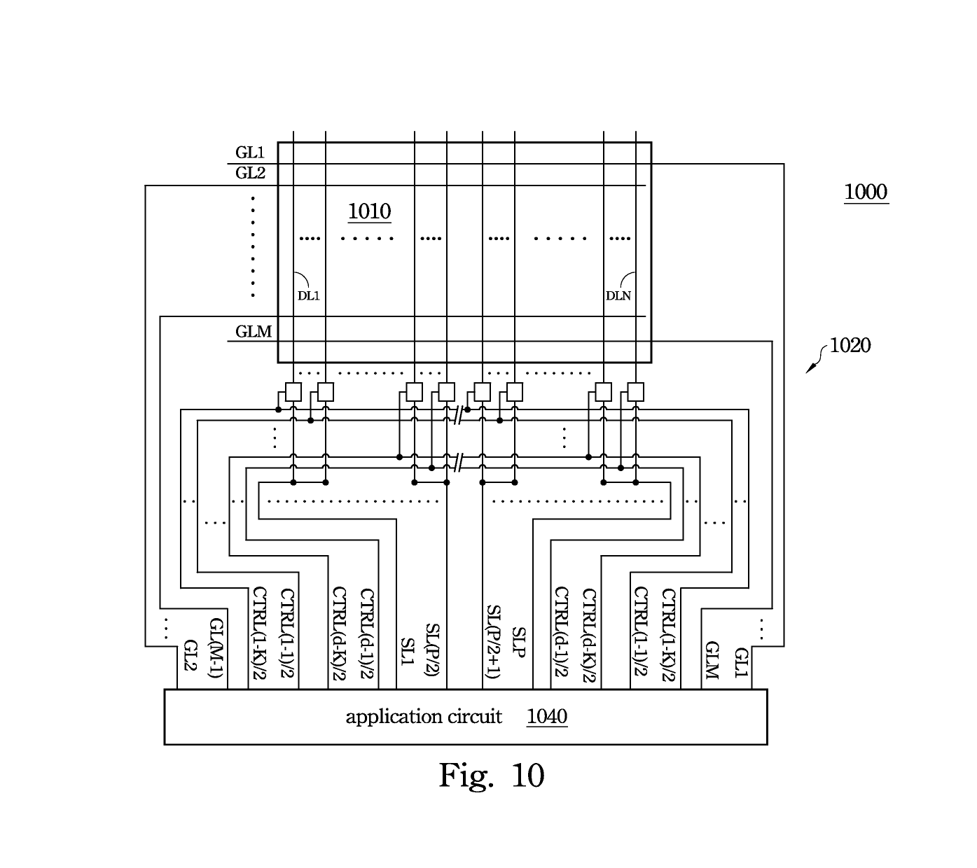

FIG. 10 is a diagram illustrating a display panel according to a seventh embodiment of the present invention. As illustrated in FIG. 10, the display panel 1000 includes a display array 1010, a multiplexer circuit 1020, an application circuit 1040 and video signal lines SL1-SLP. The connections and operations of the display array 1010, the multiplexer circuit 1020, the application circuit 1040 and the video signal lines SL1-SLP are similar to those in the embodiment shown in FIG. 7, and thus they are not further detailed hereinafter.

Compared to the embodiment in FIG. 7, the arrangements of the multiplexer circuit 1020 and the application circuit 1040 in the present embodiment are different from those of the multiplexer circuit and the application circuit shown in FIG. 7; instead, the multiplexer circuit 1020 and the application circuit 1040 are arranged below the display array 1010, which are similar to those in the embodiment shown in FIG. 8. For example, the multiplexer circuit 1020 and the application circuit 1040 are arranged at one side of the display array 1010, and each of the control lines is coupled to the control end of at least one of the switches.

Another aspect of the present disclosure is related to a method for transmitting signals, which is applicable for the display panel shown in FIG. 2 and FIG. 5 through FIG. 10. For example in conjunction with the embodiment shown in FIG. 2, a plurality of identical groups of control signals are synchronously transmitted to a plurality of groups of corresponding switches (e.g., 1^{st} group of switches M11-M1K, 2^{nd} group of switches M21-M2K, . . . , d^{th} group of switches Md1-MdK) through a plurality of groups of control lines (e.g., 1^{st} group of control lines CTRL1-1-CTRL1-K, 2nd group of control lines CTRL2-1-CTRL2-K, . . . , d^{th} group of control lines CTRLd-1-CTRLd-K). Thereafter, the multiple groups of switches are activated in accordance with the multiple groups of control signals. Then, video signals are transmitted to the data lines through a plurality of corresponding video signal lines (SL1, SL2, . . . , SLP) and the activated switches.

In one embodiment, the multiple groups of control signals are transmitted synchronously in a period of one scan signal transmitted by a scan line, each of the groups of control signals includes a plurality of clock signals, and two of the clock signals have a phase difference therebetween.

The multiplexer circuit in the present disclosure can be applied in a transistor display panel made of InGaZn Oxide (IGZO), so as to significantly reduce the RC loading caused by high electron mobility.

The steps are not necessarily recited in the sequence in which the steps are performed. That is, unless the sequence of the steps is expressly indicated, the sequence of the steps is interchangeable, and all or part of the steps may be simultaneously, partially simultaneously, or sequentially performed.

As described above, the display panel, the multiplexer circuit therein, and the method for transmitting signals in the foregoing embodiments of the present invention can be applied to reduce the RC loading and it effect on each control line by the multiple groups of control lines synchronously transmitting the control signals, and to decrease distortions of the control signals on the control lines, thereby improving the quality of the display image accordingly.

As is understood by a person skilled in the art, the foregoing embodiments of the present invention are illustrative of the present invention rather than limiting of the present invention. It is intended to cover various modifications and similar arrangements included within the spirit and scope of the appended claims, the scope of which should be accorded with the broadest interpretation so as to encompass all such modifications and similar structures.

What is claimed is:

1. A multiplexer circuit comprising:
a plurality of switches comprising a first group of switches and a second group of switches;
a first group of control lines, each of the first group of control lines coupled to a control end of at least one of the first group of switches, the first group of control lines configured to transmit a first group of control signals; and
a second group of control lines, each of the second group of control lines coupled to a control end of at least one of the second group of switches, the second group of control lines configured to synchronously and independently transmit a second group of control signals which are the same as the first group of control signals.

2. The multiplexer circuit as claimed in claim 1, wherein the first group of control lines and the second group of control lines are configured to transmit the first group of control signals and the second group of control signals, respectively, in a period of a scan signal.

3. The multiplexer circuit as claimed in claim 1, wherein the first group of control signals comprises a plurality of clock signals, and phases of the clock signals are different from one another.

4. The multiplexer circuit as claimed in claim 1, wherein the first group of control lines and the second group of control lines are coupled to control ends of different switches of the plurality of switches.

5. The multiplexer circuit as claimed in claim 1, wherein each of the switches comprises a transistor made of InGaZn oxide.

6. The multiplexer circuit as claimed in claim 1, wherein each of the control lines in the first group and the second group is coupled to the control ends of two or more than two of the switches.

7. A display panel comprising:
a plurality of scan lines;
a plurality of data lines interlacing with the scan lines; and
a multiplexer circuit comprising:
a plurality of switches, first ends of the switches coupled to one ends of the data lines; and
a plurality of groups of control lines, two of the groups of control lines coupled to control ends of different ones of the switches, respectively, the groups of control lines configured to synchronously and independently transmit a plurality of identical groups of control signals.

8. The display panel as claimed in claim 7, further comprising:
a plurality of video signal lines, each of the video signal lines coupled to second ends of the switches corresponding to one group of control lines.

9. The display panel as claimed in claim 7, further comprising:
a scan driving circuit coupled to the scan lines and configured to output the scan signals sequentially transmitted through the scan lines; and
an application circuit coupled to the video signal lines and the groups of control lines, the application circuit configured for generating video signals transmitted through the video signal lines and for generating the groups of control signals transmitted synchronously through the groups of control lines.

10. The display panel as claimed in claim 9, wherein the scan driving circuit and the application circuit are arranged at opposite sides of a display array, and each of the control lines is coupled to the control end of at least one of the switches.

11. The display panel as claimed in claim 9, wherein the scan driving circuit is arranged at a first side of a display array, the multiplexer circuit and the application circuit are arranged at a second side adjacent to the first side of the display array, and each of the control lines is coupled to the control end of at least one of the switches.

12. The display panel as claimed in claim 7, further comprising:
an application circuit coupled to the video signal lines, the groups of control lines and the scan lines, the application circuit configured for generating video signals transmitted through the video signal lines, for generating the groups of control signals transmitted synchronously through the groups of control lines, and for generating scan signals transmitted through the scan lines.

13. The display panel as claimed in claim 12, wherein the multiplexer circuit and the application circuit are arranged at one side of a display array, and each of the control lines is coupled to the control end of at least one of the switches.

14. The display panel as claimed in claim 7, wherein the groups of control lines are configured to synchronously transmit the groups of control signals in a period of one scan signal transmitted by one of the scan lines.

15. The display panel as claimed in claim 7, wherein each of the groups of control signals comprises a plurality of clock signals, and two of the clock signals have a phase difference therebetween.

16. The display panel as claimed in claim 7, wherein each control line in the groups of control lines is coupled to the control ends of two or more than two of the switches.

17. A method for transmitting signals, applicable for the display panel as claimed in claim 7, the method comprising:
synchronously transmitting a plurality of identical groups of control signals through the groups of control lines to a plurality of groups of corresponding switches;
the groups of switches activated in accordance with the groups of control signals; and
transmitting a plurality of video signals through a plurality of corresponding video signal lines and the activated switches to the data lines.

18. The method as claimed in claim 17, wherein the groups of control signals are transmitted synchronously in a period of one scan signal transmitted by a scan line, each of the groups of control signals comprise a plurality of clock signals, and two of the clock signals have a phase difference therebetween.

19. The method as claimed in claim 17, wherein each of the groups of control signals comprise a plurality of clock signals, and two of the clock signals have a phase difference therebetween.

20. The method as claimed in claim 17, wherein the groups of control signals are transmitted synchronously in a period of one scan signal transmitted by a scan line.
